(19) United States
(12) Patent Application Publication
(10) Pub. No.: US 2021/0149461 A1
(43) Pub. Date: May 20, 2021

(54) COMPUTER SYSTEM AND COMPOSITE HEAT DISSIPATION SYSTEM

(71) Applicants: INVENTEC (PUDONG) TECHNOLOGY CORPORATION, Shanghai City (CN); INVENTEC CORPORATION, Taipei City (TW)

(72) Inventors: Kai-Yang TUNG, Taipei City (TW); Hung-Ju CHEN, Taipei City (TW)

(73) Assignees: INVENTEC (PUDONG) TECHNOLOGY CORPORATION, Shanghai City (CN); INVENTEC CORPORATION, Taipei City (TW)

(21) Appl. No.: 16/714,374

(22) Filed: Dec. 13, 2019

(30) Foreign Application Priority Data
Nov. 18, 2019 (CN) 201911127182.8

(51) Int. Cl. G06F 1/20; H01L 23/46; H05K 7/20

(52) U.S. Cl. CPC G06F 1/20; H01L 23/46; H05K 7/20309; H05K 7/20263; H05K 7/20327; H05K 7/20254; H05K 7/20318

(57) ABSTRACT

A computer system connected to an external heat dissipation device and including a casing, a circuit board, a heat source, an open type heat dissipation device and a closed type heat dissipation device. The circuit board is disposed on the casing. The heat source is disposed on the circuit board. The open type heat dissipation device includes a liquid cold plate and two connectors. The liquid cold plate is disposed on the circuit board and spaced apart from the heat source. The liquid cold plate is configured to be connected to the external heat dissipation device via the two connectors. The closed type heat dissipation device includes an evaporator and a condenser that are connected to each other. The evaporator is in thermal contact with the heat source, and the condenser is in thermal contact with the liquid cold plate.

### CROSS-REFERENCE TO RELATED APPLICATIONS

This non-provisional application claims priority under 35 U.S.C. § 119(a) on Patent Application No(s). 201911127182.8 filed in China, on Nov. 18, 2019, the entire contents of which are hereby incorporated by reference.

### BACKGROUND OF THE INVENTION

### Technical Field of the Invention

The invention relates to a computer system and a composite heat dissipation system, more particularly to a computer system and a composite heat dissipation system including an open type heat dissipation device and a closed type heat dissipation device.

### Description of the Related Art

In general, liquid cooling heat dissipation assemblies for server can roughly be categorized into two types: closed type heat dissipation assembly and open type heat dissipation assembly. The closed type heat dissipation assembly includes an evaporator and a condenser. Working fluid absorbs heat generated by a heat source and evaporates at the evaporator. The internal pressure difference can trigger the vapor-phase working fluid to flow towards the condenser. The condenser dissipates the heat contained in the vapor-phase working fluid and condenses the working fluid into liquid. The condensed working fluid flows back to the evaporator with the help of gravity and the internal pressure difference. The open type heat dissipation assembly includes a liquid cold plate and a connector. The liquid cold plate is attached to the heat source and is connected to an external heat dissipation device via the connector. Since the external heat dissipation device is located outside the server, the heat dissipation device can have larger volume so as to effectively help the liquid cold plate to dissipate the heat generated by the heat source.

### SUMMARY OF THE INVENTION

One embodiment of this invention provides a computer system connected to an external heat dissipation device and including a casing, a circuit board, a heat source, an open type heat dissipation device and a closed type heat dissipation device. The circuit board is disposed on the casing. The heat source is disposed on the circuit board. The open type heat dissipation device includes a liquid cold plate and two connectors. The liquid cold plate is disposed on the circuit board and spaced apart from the heat source. The liquid cold plate is configured to be connected to the external heat dissipation device via the two connectors. The closed type heat dissipation device includes an evaporator and a condenser that are connected to each other. The evaporator is in thermal contact with the heat source, and the condenser is in thermal contact with the liquid cold plate.

Another embodiment of this invention provides a composite heat dissipation system configured to be in thermal contact with a heat source and including an open type heat dissipation device and a closed type heat dissipation device. The open type heat dissipation device includes a liquid cold plate and two connectors that are connected to each other. The closed type heat dissipation device includes an evaporator and a condenser that are connected to each other. The evaporator is configured to be in thermal contact with the heat source, and the condenser is in thermal contact with the liquid cold plate.

### BRIEF DESCRIPTION OF THE DRAWINGS

The present invention will become more fully understood from the detailed description given hereinbelow and the accompanying drawings which are given by way of illustration only and thus are not limitative of the present invention and wherein:

FIG. 1 is a perspective view of a computer system according to one embodiment of the invention and an external heat dissipation device; and

FIG. 2 is a partially enlarged cross-sectional view of the computer system in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

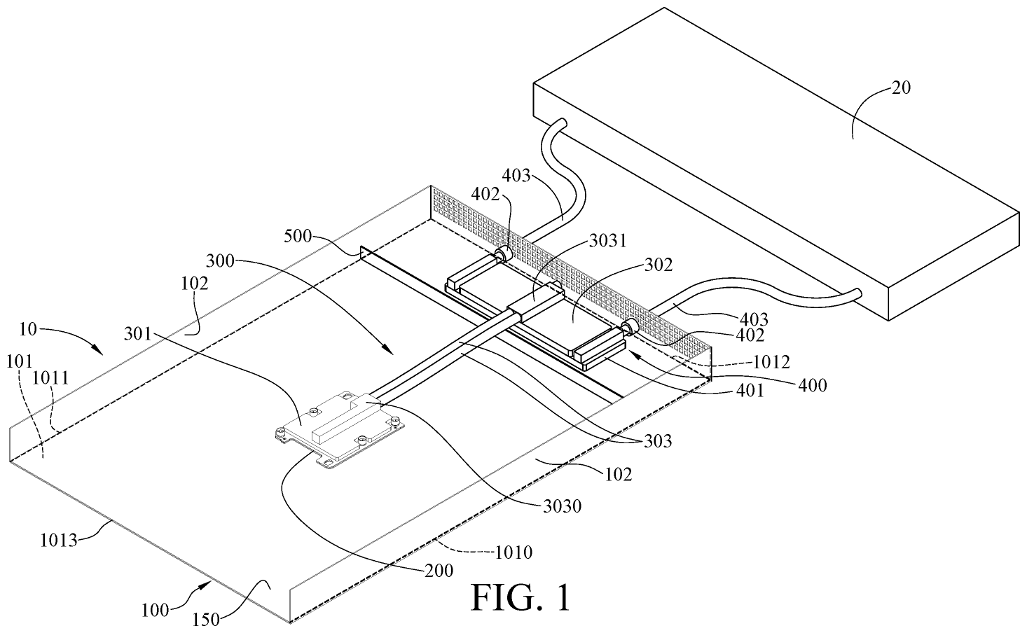

Referring to FIG. 1, a perspective view of a computer system according to one embodiment of the invention and an external heat dissipation device.

In this embodiment, a computer system 10 includes a casing 100, a circuit board 150, a heat source 200, a closed type heat dissipation device 300, an open type heat dissipation device 400, and a partition 500.

The casing 100 includes a bottom plate 101 and two side plates 102. The bottom plate 101 includes a first edge 1010, a second edge 1011, a third edge 1012, and a fourth edge 1013. The first edge 1010 and the second edge 1011 are located opposite to each other. The third edge 1012 and the fourth edge 1013 are located opposite to each other and are located between the first edge 1010 and the second edge 1011. The side plates 102 respectively stand on the first edge 1010 and the second edge 1011 of the bottom plate 101.

The circuit board 150 is disposed on the bottom plate 101. The heat source 200 is disposed on the circuit board 150. The heat source 200 is, for example, a central processing unit, but the invention is not limited thereto. In other embodiments, the heat source is a graphic processing unit or another electronic component that generates a large amount of heat during operation.

The closed type heat dissipation device 300 is, for example, a thermosiphon heat dissipation device and includes an evaporator 301, a condenser 302, two first tubes 303, and a first working fluid (not shown).

In this embodiment, the evaporator 301 is disposed on a side of the heat source 200 located away from the circuit board 150 and is in thermal contact with the heat source 200. The condenser 302 is disposed on the circuit board 150.

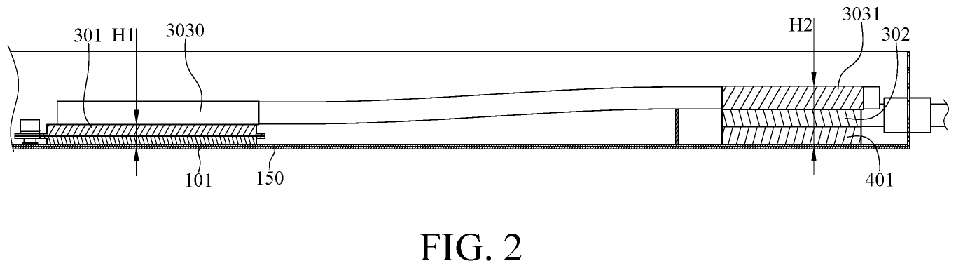

Each first tube 303 includes an evaporation portion 3030 and a condensation portion 3031 that are located opposite to each other. The evaporation portion 3030 is connected to the evaporator 301, and the condensation portion 3031 is connected to the condenser 302. Please also refer to FIG. 2, FIG. 2 shows a partially enlarged cross-sectional view of the computer system in FIG. 1, and in this embodiment, a height H1 of the evaporation portion 3030 from the bottom plate 101 is smaller than a height H2 of the condensation portion 3031 from the bottom plate 101.

However, the evaporator 301 and the condenser 302 are not limited to be connected via the first tubes 303. In other embodiments, the evaporator and the condenser are connected by any structure that allows fluid to flow through.

The first working fluid is filled in the first tubes 303. The first working fluid is, for example, a non-electrically conductive refrigerant. The evaporator 301, the condenser 302, and the first tubes 303 together form a closed loop, and there is no need to remove the first tubes 303 from the evaporator 301 or the condenser 302. Thus, the first tube 303 can be fixed to the evaporator 301 and the condenser 302 by, for example, welding, and which avoids using additional connector for the connection among the evaporator 301, the condenser 302, and the first tubes 303. As such, the leakage of the first working fluid will not occur in the junctions between the evaporator 301, the condenser 302 and the first tubes 303. Even if the leakage of the first working fluid occurs in the evaporation portion 3030 of the first tubes 303 and the first working fluid flows to the heat source 200, the first working fluid does not affect the operation of the heat source 200 due to its non-electrically conductive property. However, the first working fluid is not limited to be non-electrically conductive. In other embodiments, the first working fluid is electrically conductive. In addition, the first working fluid is not limited to be a refrigerant. In other embodiments, the first working fluid is water.

The evaporator 301 assists the evaporation of the first working fluid from the evaporation portion 3030 as the first working fluid absorbs the heat generated by the heat source 200. The vapor-phase working fluid naturally flows towards the condensation portion 3031 with the help of internal pressure difference. The condenser 302 dissipates the heat contained in the vapor-phase working fluid in the condensation portion 3031 and condenses the working fluid into liquid. Since the height H1 of the evaporation portion 3030 from the bottom plate 101 is smaller than the height H2 of the condensation portion 3031 from the bottom plate 101, the liquid-phase working fluid naturally flows back to the evaporation portion 3030 with the help of internal pressure difference and gravity.

However, the height H1 of the evaporation portion 3030 from the bottom plate 101 is not limited to be smaller than the height H2 of the condensation portion 3031 from the bottom plate 101. In other embodiments, the height of the evaporation portion from the bottom plate is larger than or equal to the height of the condensation portion from the bottom plate as long as the internal pressure difference is sufficient to return the liquid-phase working fluid to the evaporation portion.

The open type heat dissipation device 400 includes a liquid cold plate 401, two connectors 402, and two second tubes 403. In this embodiment, the liquid cold plate 401 is stacked on the circuit board 150 and is spaced apart from the heat source 200, and the condenser 302 is stacked on a side of the liquid cold plate 401 that is located away from the circuit board 150. That is, the condenser 302 is disposed on the circuit board 150 via the liquid cold plate 401. In this embodiment, the liquid cold plate 401 is located closer to the third edge 1012 of the bottom plate 101 than the heat source 200.

However, the liquid cold plate 401 is not limited to be stacked on the circuit board 150 and the condenser 302 is not limited to be stacked on the side of the liquid cold plate 401 located away from the circuit board 150. In other embodiments, the liquid cold plate is disposed on a mount fixed on the circuit board, and the condenser is not stacked on the liquid cold plate but also disposed on another mount fixed on the circuit board.

In addition, the liquid cold plate 401 is not limited to be located closer to the third edge 1012 of the bottom plate 101 than the heat source 200. In other embodiments, the liquid cold plate is disposed on any suitable place of the bottom plate as long as it is spaced apart from the heat source.

The connectors 402 are connected to the liquid cold plate 401, and the second tubes 403 are configured to respectively connect the two connectors 402 to the external heat dissipation device 20. The connectors 402 can be loosened to detach the second tubes 403 from the casing 102, which facilitates the carriage of the computer system 10. There is a second working fluid (not shown) filled in the second tubes 403. The second working fluid is, for example, water, but the invention is not limited thereto. In other embodiments, the second working fluid is a refrigerant.

However, the connectors 402 and the external heat dissipation device 20 are not limited to be connected via the second tubes 403. In other embodiments, the evaporator and the condenser are connected via any structure that allows fluid to flow through.

In addition, in this embodiment, the external heat dissipation device 20 includes a water radiator (not shown), a fan (not shown), and a pump (not shown) for the purpose of dissipating heat contained in the second working fluid in the second tubes 403, and thus the external heat dissipation device 20 is able to dissipate the heat contained in the first working fluid in the liquid cold plate 401, assisting the heat dissipation of the condenser 302. Accordingly, the closed type heat dissipation device 300 and the open type heat dissipation device 400 together form a composite heat dissipation system configured to dissipate the heat generated by the heat source 200.

The partition 500 stands on the circuit board 150 and is located between the condenser 302 and the heat source 200. Two opposite sides of the partition 500 are respectively connected to the side plates 102, such that the second working fluid is prevented from flowing to the other side of the partition 500 and flowing to the heat source 200 as the connectors 402 are loosened. However, the computer system 10 is not limited to include the partition 500. In other embodiments, the computer system does not have the partition, and there are two sealing sleeves respectively sleeved on the connectors to prevent the second working from leaking.

According to the computer system and composite heat dissipation system discussed above, the evaporator of the closed type heat dissipation device is in thermal contact with the heat source, and the liquid cold plate of the open type heat dissipation device is spaced apart from the heat source and thermally connected to the evaporator via the condenser. Thus, the working fluid of the open type heat dissipation device is unlikely to flow to and cause damage to the heat source even if the working fluid flows out of the connector of the open type heat dissipation device.

In addition, the liquid cold plate can be connected to the external heat dissipation device via the connectors of the open type heat dissipation device. For the same reason, the placement of the external heat dissipation device is not limited by the internal space of the computer system. Thus a high-efficient heat dissipation device can be employed as the external heat dissipation device and placed in a relatively large area, which helps dissipate the heat contained in the working fluid in the liquid cold plate.

As such, the composite heat dissipation system that includes the open type heat dissipation device and the closed-loop heat dissipation device can offer an improved heat dissipation efficiency while not causing damage to the heat source.

It will be apparent to those skilled in the art that various modifications and variations can be made to the present invention. It is intended that the specification and examples be considered as exemplary embodiments only, with a scope of the invention being indicated by the following claims and their equivalents.

What is claimed is:

1. A computer system, connected to an external heat dissipation device, the computer system comprising:
a casing;
a circuit board, disposed on the casing;
a heat source, disposed on the circuit board;
an open type heat dissipation device, comprising a liquid cold plate and two connectors, wherein the liquid cold plate is disposed on the circuit board and spaced apart from the heat source, and the liquid cold plate is configured to be connected to the external heat dissipation device via the two connectors; and
a closed type heat dissipation device, comprising an evaporator and a condenser that are connected to each other, wherein the evaporator is in thermal contact with the heat source, and the condenser is in thermal contact with the liquid cold plate.

2. The computer system according to claim 1, wherein the casing comprises a bottom plate and two side plates, the bottom plate comprises a first edge, a second edge, a third edge and a fourth edge, the first edge and the second edge are located opposite to each other, the third edge and the fourth edge are located opposite to each other and located between the first edge and the second edge, the two side plates respectively stand on the first edge and the second edge, the circuit board is disposed on the bottom plate, and the liquid cold plate is located closer to the third edge than the heat source.

3. The computer system according to claim 1, wherein the closed type heat dissipation device further comprises two first tubes, the two first tubes each comprise an evaporation portion and a condensation portion that are located opposite to each other, the two evaporation portions are connected to the evaporator, the two condensation portions are connected to the condenser, and a height of the two evaporation portions from the casing is smaller than a height of the two condensation portions from the casing.

4. The computer system according to claim 1, further comprising a partition, wherein the casing comprises a bottom plate and two side plates, the two side plates respectively stand on two opposite edges of the bottom plate, the circuit board is disposed on the bottom plate, the partition stands on the circuit board and is located between the condenser and the heat source, and two opposite sides of the partition are respectively connected to the two side plates.

5. The computer system according to claim 1, wherein the closed type heat dissipation device further comprises two first tubes and a first working fluid, the evaporator is connected to the condenser via the two first tubes, the first working fluid is filled in the two first tubes, and the first working fluid is non-electrically conductive.

6. The computer system according to claim 1, wherein the open type heat dissipation device further comprises two second tubes and a second working fluid, the two connectors are configured to be connected to the external heat dissipation device respectively via the two second tubes, the second working fluid is filled in the two second tubes, and the second working fluid is water.

7. The computer system according to claim 1, wherein the liquid cold plate is stacked on the circuit board.

8. The computer system according to claim 7, wherein the condenser is stacked on a side of the liquid cold plate located away from the circuit board.

9. A composite heat dissipation system, configured to be in thermal contact with a heat source, the composite heat dissipation system comprising:
an open type heat dissipation device, comprising a liquid cold plate and two connectors that are connected to each other; and
a closed type heat dissipation device, comprising an evaporator and a condenser that are connected to each other, the evaporator configured to be in thermal contact with the heat source, and the condenser is in thermal contact with the liquid cold plate.

10. The composite heat dissipation system according to claim 9, further comprising an external heat dissipation device connected to the liquid cold plate via the two connectors.
